(19) United States
(12) Patent Application Publication
(10) Pub. No.: US 2025/0151441 A1
(43) Pub. Date: May 8, 2025

(54) IMAGE SENSOR

(71) Applicant: Samsung Electronics Co., Ltd., Suwon-si (KR)

(72) Inventors: Changkyu Lee, Suwon-si (KR); Jinyoung Kim, Suwon-si (KR); Byoungho Kwon, Suwon-si (KR); Dhami Park, Suwon-si (KR); Jihun Lim, Suwon-si (KR)

(21) Appl. No.: 18/809,676

(22) Filed: Aug. 20, 2024

(30) Foreign Application Priority Data
Nov. 2, 2023 (KR) 10-2023-0150278

(51) Int. Cl. H01L 27/146

(52) U.S. Cl. CPC H10F 39/807; H10F 39/18; H10F 39/809; H10F 39/811

(57) ABSTRACT

An image sensor includes a substrate, a first pixel disposed in the substrate, the first pixel including a first photoelectric conversion region, a second pixel disposed adjacent to the first pixel in the substrate, the second pixel including a second photoelectric conversion region, a first floating diffusion region in the first pixel, a second floating diffusion region in the second pixel, an insulation layer on the substrate, and a first buried connect penetrating the insulation layer and connected to the first floating diffusion region and the second floating diffusion region, wherein the first buried connect includes an upper surface and a lower surface, the upper surface of the first buried connect is at a higher vertical level than an upper surface of the insulation layer, and the lower surface of the first buried connect is at a higher or equal vertical level than a lower surface of the insulation layer.

### CROSS-REFERENCE TO RELATED APPLICATION

This application is based on and claims priority under 35 U.S.C. § 119 to Korean Patent Application No. 10-2023-0150278, filed on Nov. 2, 2023, in the Korean Intellectual Property Office, the disclosure of which is incorporated by reference herein in its entirety.

### BACKGROUND

The inventive concept relates to an image sensor, and more particularly, to an image sensor including a photodiode.

Image sensors are devices which convert an optical image signal into an electrical signal. Image sensors include a plurality of pixels which receive incident light to convert the received light into an electrical signal and each pixel includes a photodiode region. Because the size of each pixel decreases as the degree of integration of image sensors increases, an electrical connection component of a pixel circuit for driving each pixel decreases and noise occurs with increased integration, or photoelectric conversion efficiency such as a conversion gain is reduced with the increased integration.

### SUMMARY

The inventive concept provides an image sensor having enhanced performance and reliability.

An image sensor according to an embodiment includes a substrate including a front-side surface and a backside surface opposite thereto, a first pixel disposed in the substrate, the first pixel including a first photoelectric conversion region, a second pixel disposed adjacent to the first pixel in a first horizontal direction in the substrate, wherein the first horizontal direction is a direction parallel to the front side surface of the substrate, the second pixel including a second photoelectric conversion region, a pixel isolation structure disposed between the first pixel and the second pixel, the pixel isolation structure extending in a vertical direction and surrounding each of the first pixel and the second pixel in the substrate, wherein the vertical direction is a direction normal to the front side surface of the substrate, a first floating diffusion region disposed adjacent to the front-side surface of the substrate, in the first pixel, a second floating diffusion region disposed adjacent to the front-side surface of the substrate, in the second pixel, an insulation layer disposed on the front-side surface of the substrate, and a first buried connect passing through the insulation layer and connected to the first floating diffusion region and the second floating diffusion region, wherein the first buried connect includes an upper surface disposed in the substrate and a lower surface, the upper surface of the first buried connect is disposed at a higher vertical level than an upper surface of the insulation layer, and the lower surface of the first buried connect is disposed at a vertical level which is higher than or equal to a lower surface of the insulation layer.

An image sensor according to an embodiment includes a substrate including a front-side surface and a backside surface opposite thereto, a first pixel disposed in the substrate, the first pixel including a first photoelectric conversion region, a second pixel disposed adjacent to the first pixel in a first horizontal direction in the substrate, the second pixel including a second photoelectric conversion region, wherein the first horizontal direction is a direction parallel to the front side surface of the substrate, a pixel isolation structure disposed between the first pixel and the second pixel, the pixel isolation structure extending in a vertical direction and surrounding each of the first pixel and the second pixel in the substrate, wherein the vertical direction is a direction normal to the front side surface of the substrate, a first floating diffusion region disposed adjacent to the front-side surface of the substrate, in the first pixel, a second floating diffusion region disposed adjacent to the front-side surface of the substrate, in the second pixel, an insulation layer disposed on the front-side surface of the substrate, and a buried connect passing through the insulation layer and connected to the first floating diffusion region and the second floating diffusion region, wherein an uppermost portion of a lower surface of the buried connect is disposed at a vertical level which is higher than or equal to a lower surface of the insulation layer, and an upper surface of the buried connect is disposed at higher a vertical level than the front-side surface of the substrate.

An image sensor according to an embodiment includes a substrate including a front-side surface and a backside surface opposite thereto, a first pixel disposed in the substrate, the first pixel including a plurality of first photoelectric conversion regions, a second pixel disposed adjacent to the first pixel in a first horizontal direction in the substrate, the second pixel including a plurality of second photoelectric conversion regions, wherein the first horizontal direction is a direction parallel to the front side surface of the substrate, a third pixel disposed adjacent to the first pixel in the substrate in a second horizontal direction intersecting with the first horizontal direction, the third pixel including a plurality of third photoelectric conversion regions, a fourth pixel disposed adjacent to the second pixel in the substrate in the second horizontal direction, the fourth pixel including a plurality of fourth photoelectric conversion regions, a pixel isolation structure extending in a vertical direction in the substrate, surrounding each of the first pixel, the second pixel, the third pixel, and the fourth pixel, and extending in the first horizontal direction and the second horizontal direction, wherein the vertical direction is a direction normal to the front side surface of the substrate, a first floating diffusion region disposed adjacent to the front-side surface of the substrate and shared by the plurality of first photoelectric conversion regions, in the first pixel, a second floating diffusion region disposed adjacent to the front-side surface of the substrate and shared by the plurality of second photoelectric conversion regions, in the second pixel, a third floating diffusion region disposed adjacent to the front-side surface of the substrate and shared by the plurality of third photoelectric conversion regions, in the third pixel, a fourth floating diffusion region disposed adjacent to the front-side surface of the substrate and shared by the plurality of fourth photoelectric conversion regions, in the fourth pixel, an insulation layer disposed on the front-side surface of the substrate, a buried connect contacting the first floating diffusion region to the fourth floating diffusion region and including a portion passing through the insulation layer and buried in the substrate, and a color filter and a lens, each disposed on the backside surface of the substrate, wherein the buried connect includes a material having an etch selectivity with the insulation layer, an uppermost portion of a lower surface of the buried connect is disposed at a vertical level which is higher than or equal to a lower surface of the insulation layer, and an upper surface of the buried connect is disposed at higher a vertical level than the front-side surface of the substrate.

### BRIEF DESCRIPTION OF THE DRAWINGS

Embodiments will be more clearly understood from the following detailed description taken in conjunction with the accompanying drawings in which:

FIG. 1 is a perspective view schematically illustrating an image sensor according to embodiments;

FIG. 2 is a layout view illustrating an image sensor corresponding to one pixel of FIG. 1;

FIG. 3 is a cross-sectional view taken along line A-A of FIG. 2;

FIG. 4 is a cross-sectional view taken along line B-B of FIG. 2;

FIG. 5 is an enlarged cross-sectional view of a region EX1 of FIG. 3;

FIG. 6 is an equivalent circuit diagram of an image sensor according to embodiments;

FIGS. 7 is a layout view illustrating an image sensor according to embodiments;

FIGS. 8 is a layout view illustrating an image sensor according to embodiments;

FIGS. 9 is a layout view illustrating an image sensor according to embodiments;

FIG. 10 is a perspective view schematically illustrating an image sensor according to embodiments;

FIG. 11 is a cross-sectional view taken along line C-C of FIG. 10;

FIG. 12 is a cross-sectional view illustrating a method of manufacturing an image sensor, according to embodiments;

FIG. 13 is a cross-sectional view illustrating a method of manufacturing an image sensor, according to embodiments;

FIG. 14 is a cross-sectional view illustrating a method of manufacturing an image sensor, according to embodiments;

FIG. 15 is a cross-sectional view illustrating a method of manufacturing an image sensor, according to embodiments;

FIG. 16. is a cross-sectional view illustrating a method of manufacturing an image sensor, according to embodiments; and

FIG. 17 is a block diagram illustrating a configuration of an image sensor according to an embodiment.

### DETAILED DESCRIPTION OF THE EMBODIMENTS

Hereinafter, embodiments of the inventive concept will be described in detail with reference to the accompanying drawings. The inventive concept may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Although the drawings described herein may be referred to using language such as “an embodiment,” “one embodiment,” or “certain embodiments,” these drawings, and their corresponding descriptions are not intended to be mutually exclusive from other drawings or descriptions, unless the context so indicates. Therefore, certain aspects from certain drawings may be the same as certain features in other drawings, and/or certain drawings may be different representations or different portions of a particular exemplary embodiment.

Items described in the singular herein may be provided in plural, as can be seen, for example, in the drawings. Thus, the description of a single item that is provided in plural should be understood to be applicable to the remaining plurality of items unless context indicates otherwise.

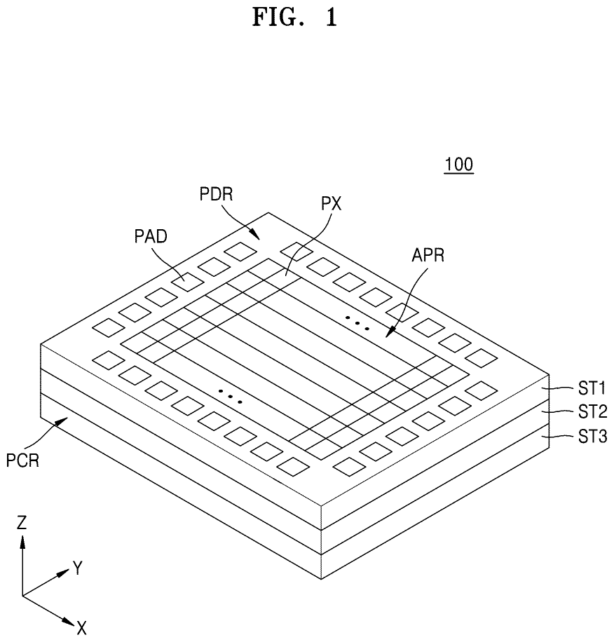

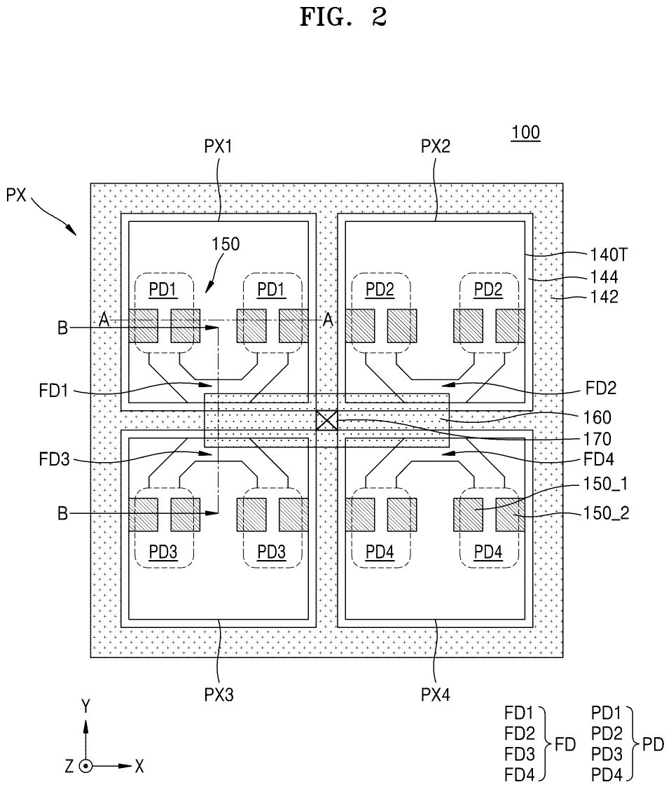

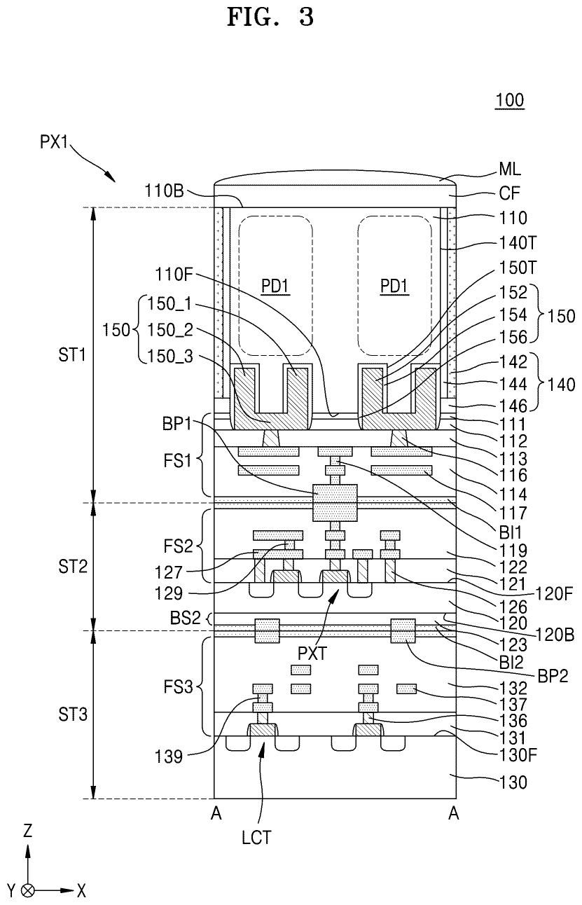

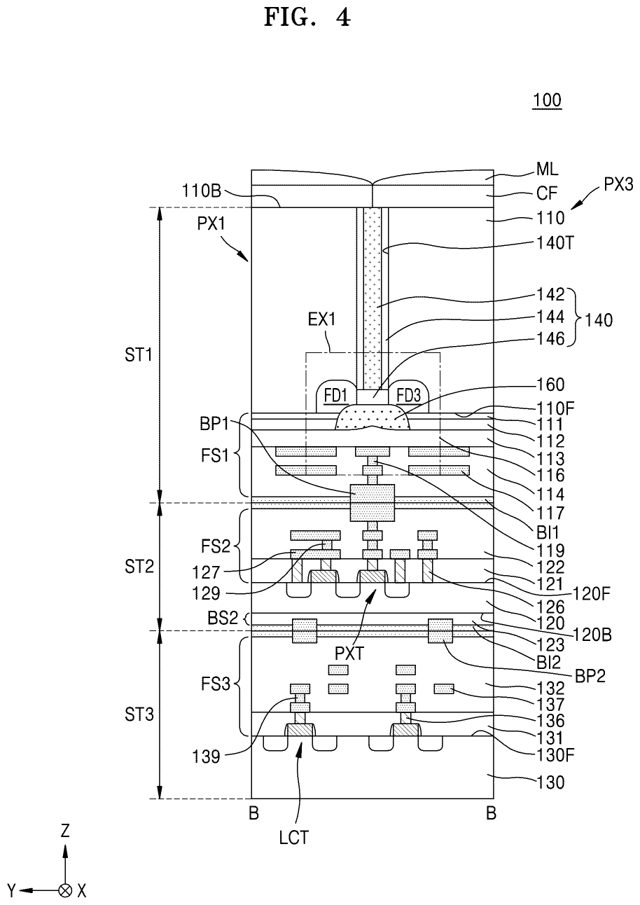

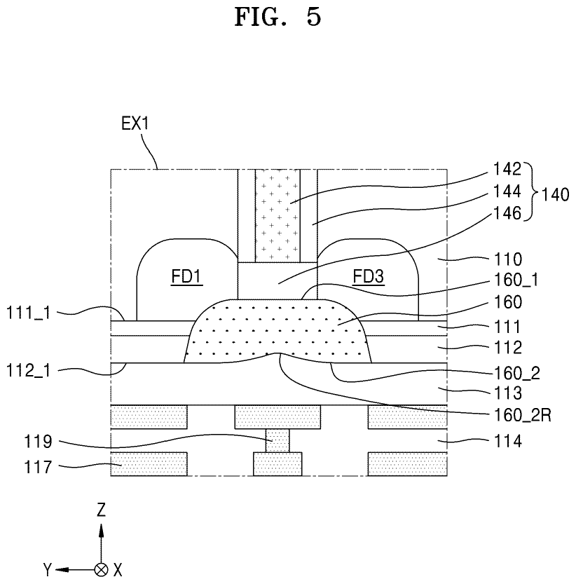

FIG. 1 is a perspective view schematically illustrating an image sensor 100 according to embodiments. FIG. 2 is a layout view illustrating the image sensor 100 corresponding to one pixel PX of FIG. 1. FIG. 3 is a cross-sectional view taken along line A-A of FIG. 2. FIG. 4 is a cross-sectional view taken along line B-B of FIG. 2. FIG. 5 is an enlarged cross-sectional view of a region EX1 of FIG. 3.

Referring to FIGS. 1 to 5, the image sensor 100 may be a stacked image sensor where a first stack ST1, a second stack ST2, and a third stack ST3 are stacked in a vertical direction.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

An active pixel region APR may be disposed at a center portion of the image sensor 100, and a plurality of pixels PX may be disposed in the active pixel region APR. Each of the plurality of pixels PX may be a region which receives light from the outside of the image sensor 100 and converts the received light into an electrical signal. The plurality of pixels PX may be disposed in the first stack ST1 and the second stack ST2 For example, a photoelectric conversion region PD for receiving external light may be disposed in the first stack ST1, and transistors configuring a pixel circuit PXC for converting a photocharge accumulated in the photoelectric conversion region PD into an electrical signal may be disposed in the second stack ST2.

A pad region PDR may be disposed on at least one side of the active pixel region APR (e.g., a lateral side), and for example, may be disposed on four side surfaces of the active pixel region APR in a plan view. A plurality of pads PAD may be disposed in the pad region PDR and may be configured to transfer and receive an electrical signal to and from an external device.

The peripheral circuit region PCR may include a logic circuit block and/or a memory device. For example, the logic circuit block may include a plurality of logic transistors LCT and may provide a certain signal to each pixel PX of the active pixel region APR or may control an output signal of each pixel PX. For example, the logic transistor LCT may include at least one of a row decoder, a row driver, a column decoder, a timing generator, a correlated double sampler (CDS), an analog-to-digital converter (ADC), and an input/output (I/O) buffer.

The active pixel region APR may include the plurality of pixels PX, and a plurality of photoelectric conversion regions PD may be respectively disposed in the plurality of pixels PX. In the active pixel region APR the plurality of pixels PX may be arranged in a matrix form including columns and rows in a first direction X which is parallel to an upper surface of a first semiconductor substrate 110 (e.g., the backside surface of the semiconductor substrate) and a second direction Y which is perpendicular to the first direction X and is parallel to the upper surface of the first semiconductor substrate 110. Some of the plurality of pixels PX may be optical black pixels (not shown). The optical black pixel may function as a reference pixel for the active pixel region APR and may perform a function of automatically correcting a dark signal.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

In some embodiments, as illustrated in FIG. 2, a first pixel PX1, a second pixel PX2, a third pixel PX3, and a fourth pixel PX4 may be arranged in a matrix form. Each of the first to fourth pixels PX1 to PX4 of the first stack ST1 may include a photoelectric conversion region PD and a floating diffusion region FD.

For example, the first pixel PX1 may include a first photoelectric conversion region PD1 and a first floating diffusion region FD1. The second pixel PX2 may include a second photoelectric conversion region PD2 and a second floating diffusion region FD2. The third pixel PX3 may include a third photoelectric conversion region PD3 and a third floating diffusion region FD3. The fourth pixel PX4 may include a fourth photoelectric conversion region PD4 and a fourth floating diffusion region FD4.

In some embodiments, two photoelectric conversion regions PD may be disposed in one pixel PX. For example, the first pixel PX1 may include two first photoelectric conversion regions PD1. For example, the second pixel PX2 may include two second photoelectric conversion regions PD2. For example, the third pixel PX3 may include two third photoelectric conversion regions PD3. For example, the fourth pixel PX4 may include two fourth photoelectric conversion regions PD4.

The first stack ST1 may include the first semiconductor substrate 110 including a front-side surface 110F and a backside surface 110B, the photoelectric conversion region PD and the floating diffusion region FD which are each formed in the first semiconductor substrate 110, a dual transfer gate 150 and a first front-side structure FS1 which are each disposed on the front-side surface 110F of the first semiconductor substrate 110, and a color filter CF and a micro-lens ML which are each disposed on the backside surface 110B of the first semiconductor substrate 110.

The second stack ST2 may include a second semiconductor substrate 120 including a front-side surface 120F and a backside surface 120B, a pixel transistor PXT and a second front-side structure FS2 which are each disposed on the front-side surface 120F of the second semiconductor substrate 120, and a backside structure BS2 disposed on the backside surface 120B of the second semiconductor substrate 120.

The third stack ST3 may include a third semiconductor substrate 130, including a front-side surface 130F, and a logic transistor LCT and a third front-side structure FS3 which are each disposed on the front-side surface 130F of the third semiconductor substrate 130.

The second stack ST2 may be disposed between the first stack ST1 and the third stack ST3, and, for example, the second front-side structure FS2 of the second stack ST2 may be disposed to face the first front-side structure FS1 of the first stack ST1 and the backside structure BS2 of the second stack ST2 may be disposed to face the third front-side structure FS3 of the third stack ST3.

In some embodiments, the first to third semiconductor substrates 110 to 130 may each include a P-type semiconductor substrate. For example, at least one of the first to third semiconductor substrates 110 to 130 may be formed of and/or include a P-type silicon substrate. In some embodiments, at least one of the first to third semiconductor substrates 110 to 130 may be formed of and/or include a P-type bulk substrate and a P-type or N-type epitaxial layer grown thereon, and in other embodiments, at least one of the first to third semiconductor substrates 110 to 130 may be formed of and/or include an N-type bulk substrate and a P-type or N-type epitaxial layer grown thereon.

A pixel isolation structure 140 may be disposed in the first semiconductor substrate 110 of the first stack ST1. The plurality of pixels PX may be defined by the pixel isolation structure 140. The pixel isolation structure 140 may include a conductive layer 142, an insulation liner 144, and an upper insulation layer 146. The conductive layer 142 may be disposed in a pixel trench 140T passing through the first semiconductor substrate 110. The insulation liner 144 may be disposed on an inner sidewall of the pixel trench 140T passing through the first semiconductor substrate 110 and may be disposed between the conductive layer 142 and the first semiconductor substrate 110 to extend up to a second surface 110F2 of the first semiconductor substrate 110 from the front-side surface 110F of the first semiconductor substrate 110. The upper insulation layer 146 may be disposed in a portion of the pixel trench 140T adjacent to the front-side surface 110F of the first semiconductor substrate 110.

In some embodiments, the pixel isolation structure 140 may pass through the first semiconductor substrate 110. For example, the pixel isolation structure 140 may be a front-side deep trench isolation (FDTI). Unlike the illustration, the pixel isolation structure 140 may not pass through the first semiconductor substrate 110. For example, the pixel isolation structure 140 may be a backside deep trench isolation (BDTI).

In some embodiments, the conductive layer 142 may be formed of and/or include at least one of doped polysilicon, metal, metal silicide, metal nitride, and a metal-containing layer. The insulation liner 144 may be formed of and/or include an insulating material such as silicon oxide, silicon nitride, and silicon oxynitride. The upper insulation liner 146 may be formed of and/or include an insulating material such as silicon oxide, silicon nitride, and silicon oxynitride.

A plurality of photoelectric conversion regions PD may be disposed in the first semiconductor substrate 110 of the first stack ST1 in the plurality of pixels PX. The photoelectric conversion region PD may be a region doped with n-type impurities. For example, the photoelectric conversion region PD may have an impurity concentration difference between an upper portion and a lower portion thereof and may thus have a potential slope. Alternatively, the photoelectric conversion region PD may be formed in a form where a plurality of impurity regions are stacked in a vertical direction.

As illustrated in FIGS. 2 and 4, the floating diffusion region FD may be disposed in an internal region of the first semiconductor substrate 110 adjacent to the front-side surface 110F of the first semiconductor substrate 110 of the first stack ST1. The floating diffusion region FD may be a region which stores electric charge transferred from an adjacent photoelectric conversion region PD. In some embodiments, two photoelectric conversion regions PD are disposed in one pixel PX and the floating diffusion region FD may be shared by the two photoelectric conversion regions PD. For example, in some embodiments, one pixel PX includes two photoelectric conversion regions PD and the floating diffusion region FD may be a region which stores electric charges transferred from two photoelectric conversion regions PD of a corresponding pixel PX.

The first floating diffusion region FD1 of the first pixel PX1 may be shared by two first photoelectric conversion regions PD1. The second floating diffusion region FD2 of the second pixel PX2 may be shared by two second photoelectric conversion regions PD2. The third floating diffusion region FD3 of the third pixel PX3 may be shared by two third photoelectric conversion regions PD3. The fourth floating diffusion region FD4 of the fourth pixel PX4 may be shared by two fourth photoelectric conversion regions PD4.

The first floating diffusion region FD1 of the first pixel PX1, the second floating diffusion region FD2 of the second pixel PX2, the third floating diffusion region FD3 of the third pixel PX3, and the fourth floating diffusion region FD4 of the fourth pixel PX4 may be isolated from one another by the pixel isolation structure 140.

A ground region (not shown) may be disposed in an internal region of the first semiconductor substrate 110 adjacent to the front-side surface 110F of the first semiconductor substrate 110 of the first stack ST1.

As illustrated in FIGS. 2 and 3, the dual transfer gate 150 may be disposed on the front-side surface 110F of the first semiconductor substrate 110 of the first stack ST1. The dual transfer gate 150 may include a first portion 150_1, a second portion 150_2, and a third portion 150_3, the first portion 150_1 and the second portion 150_2 may be disposed in the transfer gate trench 150T extending to an inner portion of the first semiconductor substrate 110 from the front-side surface 110F of the first semiconductor substrate 110, and the third portion 150_3 may be disposed on the front-side surface 110F of the first semiconductor substrate 110. The third portion 150_3 may be surrounded by a first insulation layer 111 and a second insulation layer 112 on the front-side surface 110F of the first semiconductor substrate 110. The third portion 150_3 may be connected to the first portion 150_1 and the second portion 150_2 and may be provided as one body, and the third portion 150_3 may overlap at least a portion of each of the first portion 150_1 and the second portion 150_2 in a vertical direction Z.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

In FIG. 3, it is illustrated that the front-side surface 110F of the first semiconductor substrate 110 is disposed downward toward the second stack ST2 and the backside surface 110B of the first semiconductor substrate 110 is disposed upward, and thus, the third portion 150_3 may be disposed at a vertical level which is lower than the front-side surface 110F of the first semiconductor substrate 110. For example, a distance between the third portion 150_2 and the second stack ST2 in the vertical direction Z may be set to be less than a distance between the front-side surface 110F of the first semiconductor substrate 110 and the second stack ST2 in the vertical direction Z.

In detail, two dual transfer gates 150 respectively corresponding to the two first photoelectric conversion regions PD1 of the first pixel PX1 may be disposed. The dual transfer gate 150 may be adjacent to the front-side surface 110F of the first semiconductor substrate 110. The two dual transfer gates 150 respectively corresponding to the two first photoelectric conversion regions PD1 of the first pixel PX1 may be shared by the first floating diffusion region FD1 of the first pixel PX1.

In some embodiments, a transfer gate insulation layer 154 may be disposed on an inner wall of the transfer gate trench 150T. The transfer gate insulation layer 154 may be disposed between the dual transfer gate electrode 152 and the first semiconductor substrate 110 to have a relatively uniform thickness.

In some embodiments, a spacer 156 may be disposed on a sidewall of a transfer gate electrode 152 of the third portion 150_3 of the dual transfer gate 150 and may be disposed on the front-side surface 110F of the first semiconductor substrate 110.

As illustrated in FIGS. 3 and 4, the first front-side structure FS1 may be disposed on the front-side surface 110F of the first semiconductor substrate 110 of the first stack ST1. The first front-side structure FS1 may include a first insulation layer 111 and a second insulation layer 112, which are disposed on the front-side surface 110F of the first semiconductor substrate 110. For example, the first insulation layer 111 and the second insulation layer 112 may be formed of and/or include at least one of silicon oxide, silicon nitride, silicon oxynitride, and silicon carbon nitride. For example, the first insulation layer 111 may be formed of and/or include silicon oxide, and the second insulation layer 112 may be formed of and/or include silicon nitride. Furthermore, each of the first and second insulation layers 111 and 112 may be formed in a stack structure with a plurality of insulation layers (not shown), and an additional insulation liner (not shown) may be further disposed between two adjacent insulation layers of the plurality of insulation layers.

As illustrated in FIG. 4, a buried connect 160 (e.g., a buried conductive element) which passes through the first insulation layer 111 and the second insulation layer 112 of the first front-side structure FS1 of the first stack ST1 and is connected to the first floating diffusion region FD1 of the first pixel PX1 and the third floating diffusion region FD3 of the third pixel PX3 may be disposed in the first stack ST1.

The term “buried” may refer to structures, patterns, and/or layers that are formed at least partially below a top surface of another structure, pattern, and/or layer. In some embodiments, when a first structure, pattern, and/or layer is “buried” in a second structure, pattern, and/or layer, the second structure, pattern, and/or layer may surround at least a portion of the first structure, pattern, and/or layer. For example, a first structure, pattern, and/or layer first may be considered to be buried when it is at least partially embedded in a second structure, pattern, and/or layer.

In detail, referring to FIG. 5, the buried connect 160 may pass through the first insulation layer 111 and the second insulation layer 112 and may be buried from the front-side surface 110F of the first semiconductor substrate 110 into the first semiconductor substrate 110. For example, the buried connect 160 may include a portion surrounded by the first insulation layer 111 and the second insulation layer 112 and a portion buried in the first semiconductor substrate 110.

In some embodiments, the first floating diffusion region FD1 of the first pixel PX1 and the third floating diffusion region FD3 of the third pixel PX3 adjacent to each other in the second horizontal direction (the Y direction) may be spaced apart from each other in the second horizontal direction (the Y direction) with the pixel isolation structure 140 therebetween.

In some embodiments, the first floating diffusion region FD1 of the first pixel PX1 and the third floating diffusion region FD3 of the third pixel PX3 may be electrically connected with each other by the buried connect 160. In detail, each of the first floating diffusion region FD1 of the first pixel PX1 and the third floating diffusion region FD3 of the third pixel PX3 may contact and be electrically connected to the buried connect 160.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

In some embodiments, the buried connect 160 may overlap the pixel isolation structure 140 in the vertical direction (the Z direction). For example, the buried connect 160 may include a portion which is buried toward a portion of the pixel isolation structure 140 adjacent to the front-side surface 110F of the first semiconductor substrate 110.

In some embodiments, the buried connect 160 may include portions each which overlaps the first floating diffusion region FD1 of the first pixel PX1 and the third floating diffusion region FD3 of the third pixel PX3 in the vertical direction (the Z direction). The buried connect 160 may include a portion which is disposed between the first floating diffusion region FD1 of the first pixel PX1 and the third floating diffusion region FD3 of the third pixel PX3. The buried connect 160 may include a portion which overlaps the first floating diffusion region FD1 of the first pixel PX1 and the third floating diffusion region FD3 of the third pixel PX3 in the second horizontal direction (the Y direction).

In some embodiments, the buried connect 160 may include an upper surface 160_1 disposed in the first semiconductor substrate 110 and a lower surface 160_2 opposite to the upper surface 160_1. The first insulation layer 111 may include an upper surface 111_1 facing the front-side surface 110F of the first semiconductor substrate 110. The second insulation layer 112 may include a lower surface 112_1 opposite to the upper surface 111_1 of the first insulation layer 111. The upper surface 111_1 of the first insulation layer 111 may be a surface contacting the front-side surface 110F of the first semiconductor substrate 110. The lower surface 112_1 of the second insulation layer 112 may be a surface contacting the third insulation layer 113.

The upper surface 160_1 of the buried connect 160 may be disposed at a vertical level which is higher than the upper surface 111_1 of the first insulation layer 111. The upper surface 160_1 of the buried connect 160 may be disposed at a vertical level which is higher than the front-side surface 110F of the first semiconductor substrate 110. Herein, being disposed at a high or low vertical level may denote being disposed at a higher or lower vertical level in a +Z direction.

The lower surface 160_2 of the buried connect 160 may be disposed at a vertical level which is higher than or equal to the lower surface 112_1 of the second insulation layer 112. In detail, the lower surface 160_2 of the buried connect 160 may include a portion disposed at a vertical level which is equal to the lower surface 112_1 of the second insulation layer 112. In detail, the lower surface 160_2 of the buried connect 160 may include a portion disposed at a vertical level which is higher than the lower surface 112_1 of the second insulation layer 112.

In some embodiments, the lower surface 160_2 of the buried connect 160 may include a recess portion 160_2R. In detail, the lower surface 160_2 of the buried connect 160 may be recessed to an inner portion of the buried connect 160. For example, the recess portion 160_2R of the lower surface 160_2 of the buried connect 160 may be recessed toward the upper surface 160_1 of the buried connect 160.

In some embodiments, the recess portion 160_2R of the buried connect 160 may overlap the pixel isolation structure 140 in the vertical direction (the Z direction).

Unlike the illustration, the buried connect 160 may not include the recess portion 160_2R, and the lower surface 160_2 of the buried connect 160 may be disposed at a vertical level which is equal to the lower surface 112_1 of the second insulation layer 112.

The lower surface 160_2 of the buried connect 160 may be disposed at a vertical level which is lower than the upper surface 111_1 of the first insulation layer 111. The lower surface 160_2 of the buried connect 160 may be disposed at a vertical level which is lower than the front-side surface 110F of the first semiconductor substrate 110. The lower surface 160_2 of the buried connect 160 may be disposed at a vertical level which is lower than an upper surface of the second insulation layer 112.

In some embodiments, the buried connect 160 may have an etch selectivity corresponding to each of the first insulation layer 111 and the second insulation layer 112. For example, the buried connect 160 may include a material having an etch selectivity corresponding to silicon oxide, silicon nitride, silicon oxynitride, or silicon carbon nitride. For example, the buried connect 160 may include polysilicon and/or doped polysilicon. For example, the buried connect 160 may include metal such as tungsten (W) and/or copper (Cu).

As illustrated in FIG. 2, the buried connect 160 may overlap the first floating diffusion region FD1 of the first pixel PX1, the second floating diffusion region FD2 of the second pixel PX2, the third floating diffusion region FD3 of the third pixel PX3, and the fourth floating diffusion region FD4 of the fourth pixel PX4 in the vertical direction (the Z direction).

As described above, the buried connect 160 may be connected to each of the first floating diffusion region FD1 of the first pixel PX1, the second floating diffusion region FD2 of the second pixel PX2, the third floating diffusion region FD3 of the third pixel PX3, and the fourth floating diffusion region FD4 of the fourth pixel PX4. The buried connect 160 may contact and be electrically connected to each of the first floating diffusion region FD1 of the first pixel PX1, the second floating diffusion region FD2 of the second pixel PX2, the third floating diffusion region FD3 of the third pixel PX3, and the fourth floating diffusion region FD4 of the fourth pixel PX4.

Referring again to FIGS. 3 and 4, the first front-side structure FS1 may include a third insulation layer 113 and a fourth insulation layer 114, which are disposed on the first insulation layer 111 and the second insulation layer 112. The first front-side structure FS1 may further include a conductive via 116 passing through the third insulation layer 113, and a wiring layer 117 and a via 119 each disposed in the fourth insulation layer 114.

In some embodiments, a contact 170 (see FIG. 2) passing through the third insulation layer 113 may be disposed on the buried connect 160 passing through the first insulation layer 111 and the second insulation layer 112. The buried connect 160 may be connected to the wiring layer 117 and the via 119 each disposed in the fourth insulation layer 114 by using the contact 170. As described above, because the buried connect 160 contacts the first to fourth floating diffusion regions FD1 to FD4, the contact 170 may be connected to the first to fourth floating diffusion regions FD1 to FD4.

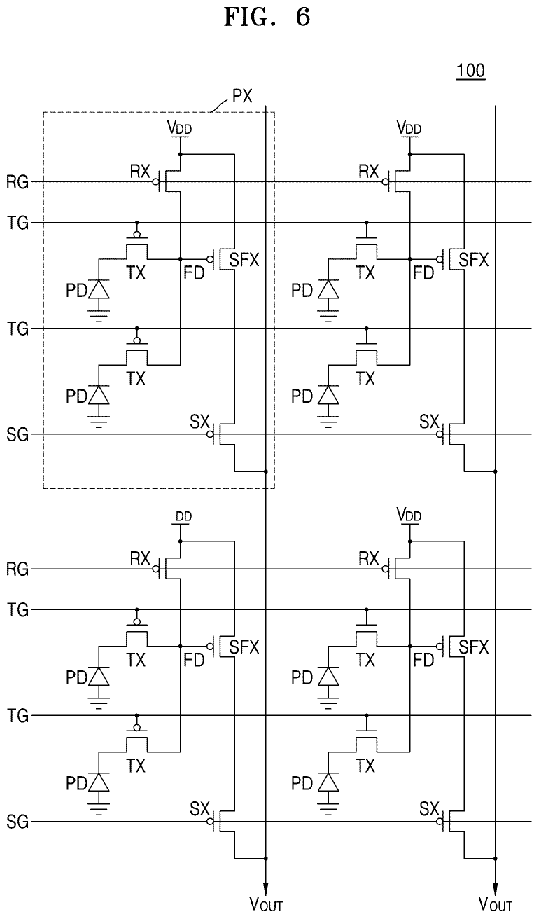

The second front-side structure FS2 may be disposed on the front-side surface 120F of the second semiconductor substrate 120 of the second stack ST2. The second front-side structure FS2 may include a first insulation layer 121 and a second insulation layer 122, which are disposed on the front-side surface 120F of the second semiconductor substrate 120. The first insulation layer 121 may cover the pixel transistor PXT disposed on the front-side surface 120F of the second semiconductor substrate 120. The second front-side structure FS2 may further include a conductive via 126 passing through the first insulation layer 121, and a wiring layer 127 and a via 129 each disposed in the second insulation layer 122. The conductive via 126, the wiring layer 127, and the via 129 may be disposed to be electrically connected to the pixel transistor PXT. In some embodiments, the pixel transistor PXT may include a reset transistor RX, a selection transistor SX, and a source follower transistor SFX (see FIG. 6).

The backside structure BS2 may be disposed on the backside surface 120B of the second semiconductor substrate 120 of the second stack ST2. The backside structure BS2 may include a third insulation layer 123 which is disposed on the backside surface 120B of the second semiconductor substrate 120.

The third front-side structure FS3 may be disposed on the front-side surface 130F of the third semiconductor substrate 130 of the third stack ST3. The third front-side structure FS3 may include a first insulation layer 131 and a second insulation layer 132, which are disposed on the front-side surface 130F of the third semiconductor substrate 130. The first insulation layer 131 may cover the logic transistor LCT disposed on the front-side surface 130F of the third semiconductor substrate 130. The third front-side structure FS3 may further include a conductive via 136 passing through the first insulation layer 131, and a wiring layer 137 and a via 139 each disposed in the second insulation layer 132. The conductive via 136, the wiring layer 137, and the via 139 may be disposed to be electrically connected to the logic transistor LCT.

In some embodiments, the conductive vias 116, 126, and 136, the wiring layers 117, 127, and 137, and the vias 119, 129, and 139 may be formed of and/or include at least one of copper (Cu), aluminum (Al), tungsten (W), titanium (Ti), titanium nitride (TiN), tantalum (Ta), tantalum nitride (TaN), ruthenium (Ru), and tungsten nitride (WN).

As illustrated in FIGS. 3 and 4, the second front-side structure FS2 of the second stack ST2 may be disposed to face the first front-side structure FS1 of the first stack ST1. A first bonding layer BI1 may be disposed between the first front-side structure FS1 and the second front-side structure FS2. The backside structure BS2 of the second stack ST2 may be disposed to face the third front-side structure FS3 of the third stack ST3. A second bonding layer BI2 may be disposed between the backside structure BS1 and the third front-side structure FS3. Each of the first bonding layer BI1 and the second bonding layer BI2 may be formed in a stack structure of a plurality of insulation layers, and for example, may be formed of and/or include at least one of silicon oxide, silicon nitride, silicon oxynitride, or silicon carbon nitride.

In some embodiments, a first bonding pad BP1 may be disposed at a boundary between the first stack ST1 and the second stack ST2. The first bonding pad BP1 may be surrounded by the first bonding layer BI1. The first bonding pad BP1 may include an upper pad part of the first stack ST1 and a lower pad part of the second stack ST2, and the upper pad part and the lower pad part may be disposed to overlap each other and may be attached on each other. For example, an interface (for example, a bonding interface) between the upper pad part and the lower pad part may be disposed between the first front-side structure FS1 and the second front-side structure FS2. The first bonding pad BP1 may be formed of and/or include copper. For example, the first stack ST1 and the second stack ST2 may be stacked by a metal-oxide hybrid bonding process.

In some embodiments, a second bonding pad BP2 may be disposed at a boundary between the second stack ST2 and the third stack ST3. The second bonding pad BP2 may be surrounded by the second bonding layer BI2. The second stack ST2 and the third stack ST3 may be stacked by a metal-oxide hybrid bonding process. The second bonding pad BP2 may be formed of and/or include copper.

According to embodiments, the image sensor 100 including the buried connect 160 may be provided. The buried connect 160 may connect floating diffusion regions FD of pixels PX which are adjacent to and apart from each other with the pixel isolation structure 140 therebetween. Therefore, it may not be required to form a contact which is separately connected to each of floating diffusion regions FD of pixels PX adjacent to each other, or the number of desired contacts may be reduced, and thus, capacitance caused by the contact may decrease. Accordingly, photoelectric conversion efficiency such as a conversion gain and noise may be improved. That is, according to embodiments, the image sensor 100 having enhanced performance and reliability may be provided.

FIG. 6 is an equivalent circuit diagram of an image sensor 100 according to embodiments.

Referring to FIG. 6, a plurality of pixels PXT may be arranged in a matrix form. Each of the plurality of pixels PXT may include a transfer transistor TX and pixel transistors (not shown). Here, the pixel transistors may include a reset transistor RX, a selection transistor SX, and a source follower transistor SFX. The reset transistor RX may include a reset gate RG, the selection transistor SX may include a selection gate SG, the source follower transistor SFX may include a source follower gate (not shown), and the transfer transistor TX may include a transfer gate TG. The transfer gate TG may correspond to the dual transfer gate 150 described above with reference to FIGS. 1 to 5.

Each of the plurality of pixels PX may further include a photoelectric diffusion region PD and a floating diffusion region FD. The photoelectric diffusion region PD may correspond to the photoelectric diffusion region PD described above with reference to FIGS. 1 to 5. The photoelectric diffusion region PD may generate and accumulate photocharges in proportion to the amount of light incident from the outside and may use a photodiode, a photo transistor, a photo gate, a pinned photodiode (PPD), and a combination thereof.

In some embodiments, each of the plurality of pixels PX may include two photoelectric diffusion regions PD, two transfer transistors TX, and one floating diffusion regions FD.

The transfer gate TG may transfer electric charge, generated in the photoelectric diffusion region PD, to the floating diffusion region FD. For example, each of two transfer gates TG of one pixel PX may transfer electric charge, generated in each of two photoelectric diffusion regions PD, to the floating diffusion region FD. The floating diffusion region FD may accumulate and store electric charges which are generated and transferred by the photoelectric diffusion region PD. The source follower transistor SFX may be controlled based on the amount of photocharges accumulated in the floating diffusion region FD.

The reset transistor RX may periodically reset electric charges accumulated in the floating diffusion region FD. A drain electrode of the reset transistor RX may be connected to the floating diffusion region FD, and a source electrode may be connected to a source voltage V_{DD}. When the reset transistor RX is turned on, the source voltage V_{DD} connected to the source electrode of the reset transistor RX may be transferred to the floating diffusion region FD. When the reset transistor RX is turned on, electric charges accumulated in the floating diffusion region FD may be discharged and thus, the floating diffusion region FD may be reset.

The source follower transistor SFX may be connected to a current source (not shown) disposed outside the plurality of pixels PX to function as a source follower buffer amplifier and may use an electric potential variation in the floating diffusion region FD to output an amplified voltage to an output line V_{OUT}.

The selection transistor SX may select a plurality of pixels PX by row units, and when the selection transistor SX is turned on, the source voltage V_{DD} may be transferred to a source electrode of the source follower transistor SFX.

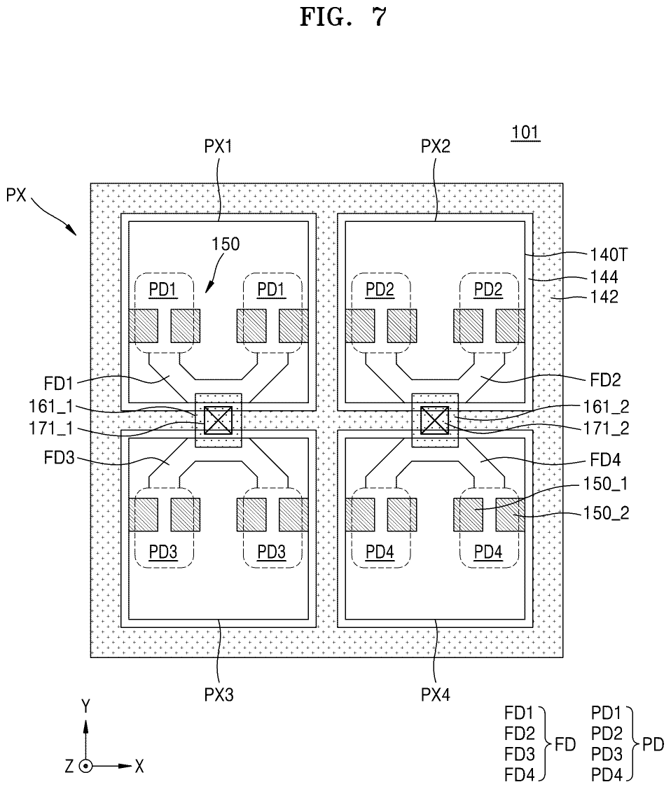

FIGS. 7 to 9 are layout views illustrating image sensors 101, 102, and 103 according to embodiments. Hereinafter, the difference with the image sensor 100 described above with reference to FIGS. 1 to 5 will be mainly described.

Referring to FIG. 7, the image sensor 101 may include a first pixel PX1, a second pixel PX2, a third pixel PX3, and a fourth pixel PX4. Like the image sensor 100 described above with reference to FIGS. 1 to 5, each of the first pixel PX1, the second pixel PX2, the third pixel PX3, and the fourth pixel PX4 of the image sensor 101 may include two photoelectric conversion regions PD, and the two photoelectric conversion regions PD may share one floating diffusion region FD.

In some embodiments, a first buried connect 161_1 may be disposed to overlap the first floating diffusion region FD1 of the first pixel PX1 and the third floating diffusion region FD3 of the third pixel PX3, which are adjacent to each other in the second horizontal direction (the Y direction), in the vertical direction (the Z direction). Likewise, a second buried connect 161_2 may be disposed to overlap the second floating diffusion region FD2 of the second pixel PX2 and the fourth floating diffusion region FD4 of the fourth pixel PX4, which are adjacent to each other in the second horizontal direction (the Y direction), in the vertical direction (the Z direction).

The first buried connect 161_1 may be connected to the first floating diffusion region FD1 and the third floating diffusion region FD3. The first buried connect 161_1 may contact the first floating diffusion region FD1 and the third floating diffusion region FD3.

The second buried connect 161_2 may be connected to the second floating diffusion region FD2 and the fourth floating diffusion region FD4. The second buried connect 161_2 may contact the second floating diffusion region FD2 and the fourth floating diffusion region FD4.

Unlike the image sensor 100 of FIG. 1 which includes the buried connect 160 connected to all of the first to fourth floating diffusion regions FD1 to FD4, the image sensor 101 may include two buried connects (i.e., the first buried connect 161_1 and the second buried connect 161_2) respectively connected to two floating diffusion regions FD.

A first contact 171_1 may be disposed on the first buried connect 161_1. The first contact 171_1 may be connected to the first floating diffusion region FD1 and the third floating diffusion region FD3 by the first buried connect 161_1. A second contact 171_2 may be disposed on the second buried connect 161_2. The second contact 171_2 may be connected to the second floating diffusion region FD2 and the fourth floating diffusion region FD4 by the second buried connect 161_2.

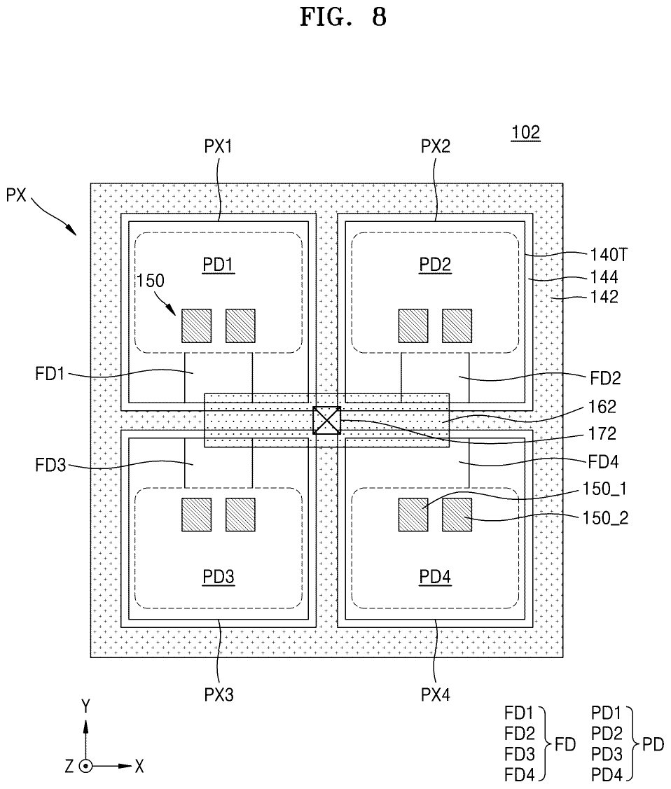

Referring to FIG. 8, the image sensor 102 may include a first pixel PX1, a second pixel PX2, a third pixel PX3, and a fourth pixel PX4. Unlike the image sensor 100 described above with reference to FIGS. 1 to 6, each of the first pixel PX1, the second pixel PX2, the third pixel PX3, and the fourth pixel PX4 of the image sensor 102 may include one photoelectric conversion region PD and one floating diffusion region FD.

In some embodiments, a buried connect 162 may be disposed to overlap a first floating diffusion region FD1 of the first pixel PX1, a second floating diffusion region FD2 of the second pixel PX2, a third floating diffusion region FD3 of the third pixel PX3, and a fourth floating diffusion region FD4 of the fourth pixel PX4 in a vertical direction (a Z direction).

The buried connect 162 may be connected to the first to fourth floating diffusion regions FD1 to FD4. The buried connect 162 may contact the first to fourth floating diffusion regions FD1 to FD4.

A contact 172 may be disposed on the buried connect 162. The contact 172 may be connected to the first to fourth floating diffusion regions FD1 to FD4 by the buried connect 162.

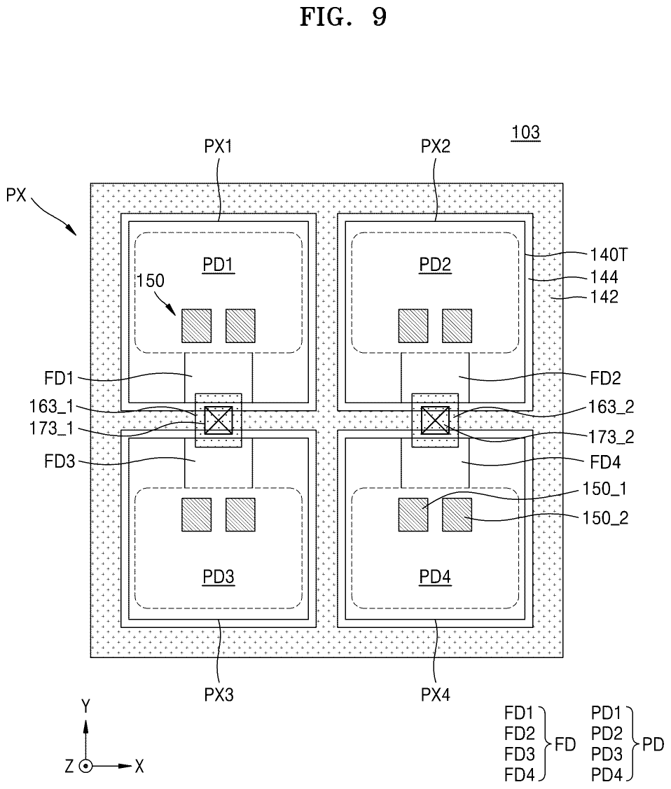

Referring to FIG. 9, the image sensor 103 may include a first pixel PX1, a second pixel PX2, a third pixel PX3, and a fourth pixel PX4. Each of the first pixel PX1, the second pixel PX2, the third pixel PX3, and the fourth pixel PX4 of the image sensor 103 may include one photoelectric conversion region PD and one floating diffusion region FD.

In some embodiments, a first buried connect 163_1 may be disposed to overlap a first floating diffusion region FD1 of the first pixel PX1 and a third floating diffusion region FD3 of the third pixel PX3, which are adjacent to each other in a second horizontal direction (a Y direction), in a vertical direction (a Z direction). Likewise, a second buried connect 163_2 may be disposed to overlap a second floating diffusion region FD2 of the second pixel PX2 and a fourth floating diffusion region FD4 of the fourth pixel PX4, which are adjacent to each other in the second horizontal direction (the Y direction), in the vertical direction (the Z direction).

The first buried connect 163_1 may be connected to the first floating diffusion region FD1 and the third floating diffusion region FD3. The first buried connect 163_1 may contact the first floating diffusion region FD1 and the third floating diffusion region FD3.

The second buried connect 163_2 may be connected to the second floating diffusion region FD2 and the fourth floating diffusion region FD4. The second buried connect 163_2 may contact the second floating diffusion region FD2 and the fourth floating diffusion region FD4.

A first contact 173_1 may be disposed on the first buried connect 163_1. The first contact 173_1 may be connected to the first floating diffusion region FD1 and the third floating diffusion region FD3 by the first buried connect 163_1. A second contact 173_2 may be disposed on the second buried connect 163_2. The second contact 173_2 may be connected to the second floating diffusion region FD2 and the fourth floating diffusion region FD4 by the second buried connect 163_2.

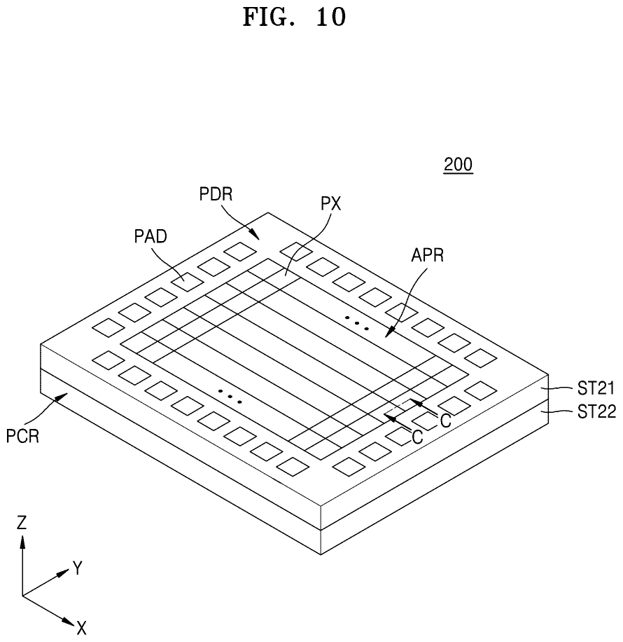

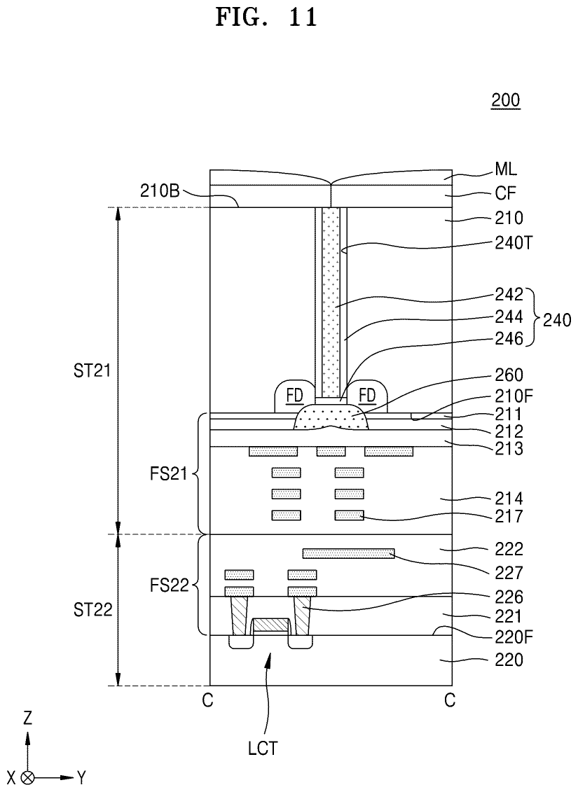

FIG. 10 is a perspective view schematically illustrating an image sensor 200 according to embodiments. FIG. 11 is a cross-sectional view taken along line C-C of FIG. 10. Hereinafter, the difference with the image sensor 100 described above with reference to FIGS. 1 to 5 will be mainly described.

Referring to FIGS. 10 and 11, the image sensor 200 may be a stacked image sensor where a first stack ST21 and a second stack ST22 are stacked in a vertical direction.

In some embodiments, a plurality of pixels PX, a photoelectric conversion region PD, and a plurality of pixel transistors may be disposed in the first stack ST21. A peripheral circuit region PCR may be disposed in the second stack ST22 and may include a logic circuit block and/or a memory device. For example, the logic circuit block may include a plurality of logic transistors LCT.

The first stack ST21 may include a first semiconductor substrate 210, a first front-side structure FS21 disposed on a first surface 210F of the first semiconductor substrate 210, and a color filter CF and a micro-lens ML each disposed on a second surface 210B of the first semiconductor substrate 210. The second stack ST22 may include a second semiconductor substrate 220 and a second front-side structure FS22 disposed on a first surface 220F of the second semiconductor substrate 220.

For example, the second front-side structure FS22 of the second stack ST22 may be disposed to face and contact the first front-side structure FS21 of the first stack ST21.

In some embodiments, the first front-side structure FS21 may include a first insulation layer 211 and a second insulation layer 212, which are disposed on a front-side surface 110F of the first semiconductor substrate 110.

The first front-side structure FS21 may include a third insulation layer 213 and a fourth insulation layer 214, which are disposed on the first insulation layer 211 and the second insulation layer 212. The first front-side structure FS21 may further include a wiring layer 217 which is disposed in the fourth insulation layer 214.

The second front-side structure FS22 may include a first insulation layer 221 and a second insulation layer 222, which are disposed on the first surface 220F of the second semiconductor substrate 220. The first insulation layer 221 may cover the logic transistor LCT disposed on the first surface 220F of the second semiconductor substrate 220. The second front-side structure FS22 may further include a conductive via 226 passing through the first insulation layer 221, and a wiring layer 127 disposed in the second insulation layer 222. The conductive via 226 and the wiring layer 227 may be disposed to be electrically connected to the logic transistor LCT.

In the first stack ST21 and the second stack ST22, the first front-side structure FS21 and the second front-side structure FS22 may be disposed to face each other, and for example, the fourth insulation layer 412 of the first front-side structure FS21 may be disposed to contact the second insulation layer 222 of the second front-side structure FS22.

A pixel isolation structure 240 may be disposed in the first semiconductor substrate 210 of the first stack ST21. The plurality of pixels PX may be defined by the pixel isolation structure 240. The pixel isolation structure 240 may include a conductive layer 242, an insulation liner 244, and an upper insulation layer 246.

A plurality of photoelectric conversion regions (not shown) may be respectively disposed in first stacks ST21 of the plurality of pixels PX. For example, one or more photoelectric conversion regions may be disposed in each pixel PX.

The floating diffusion region FD may be disposed in an internal region of the first semiconductor substrate 110 adjacent to the front-side surface 210F of the first semiconductor substrate 210 of the first stack ST21. Floating diffusion regions FD disposed in a plurality of adjacent pixels PX may be apart from each other with the pixel isolation structure 240 therebetween.

In some embodiments, the buried connect 260 may pass through a first insulation layer 111 and a second insulation layer 112 and may be connected to floating diffusion regions FD disposed in a plurality of adjacent pixels PX. For example, the buried connect 260 may be connected to a floating diffusion region FD of each of a plurality of pixels PX adjacent to each other in a first horizontal direction (an X direction) and/or a second horizontal direction (a Y direction). The buried connect 260 may overlap the pixel isolation structure 240 in a vertical direction (a Z direction). A description of the buried connect 260 may refer to the buried connect 160 described above with reference to FIGS. 1 to 6.

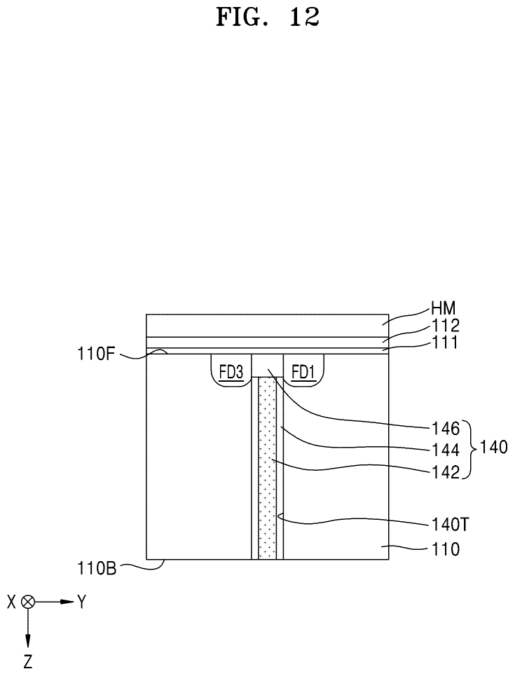

FIGS. 12 to 16 are cross-sectional views illustrating a method of manufacturing an image sensor 100, according to embodiments. In detail, FIGS. 12 to 16 are cross-sectional views corresponding to a cross-sectional surface taken along line B-B of FIG. 2.

Referring to FIG. 12, a pixel isolation structure 140 and floating diffusion regions FD1 and FD3 may be formed in a first semiconductor substrate 110. Subsequently, a first insulation layer 111 and a second insulation layer 112 may be formed on a front-side surface 110F of the first semiconductor substrate 110. The first insulation layer 111 and the second insulation layer 112 may be formed on the front-side surface 110F of the first semiconductor substrate 110 when the front-side surface 110F of the first semiconductor substrate 110 is provided upwards.

Subsequently, a hard mask layer HM may be formed on the first insulation layer 111 and the second insulation layer 112. In some embodiments, the hard mask layer HM may be a layer which has been used in a previous process. For example, the hard mask layer HM may be reused instead of being newly formed after a previous process is performed.

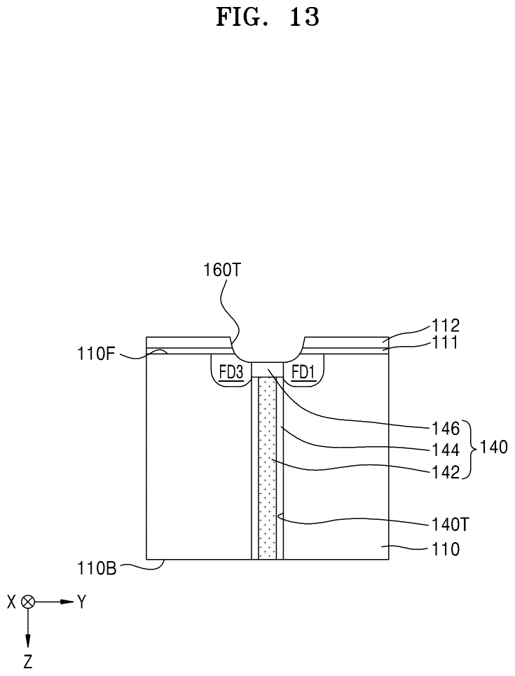

Referring to FIG. 13, a photo mask layer (not shown) may be formed on the hard mask layer HM, and a buried connect trench 160T may be formed by patterning the hard mask layer HM, the first insulation layer 111, and the second insulation layer 112. The buried connect trench 160T may be formed by etching a portion of each of the hard mask layer HM, the first insulation layer 111, the second insulation layer 112, and the floating diffusion regions FD1 and FD3 of the first semiconductor substrate 110. The portion of each of the floating diffusion regions FD1 and FD3 may be exposed by the buried connect trench 160T.

In some embodiments, a portion of the pixel isolation structure 140 may be etched together. Subsequently, the hard mask layer HM may be removed.

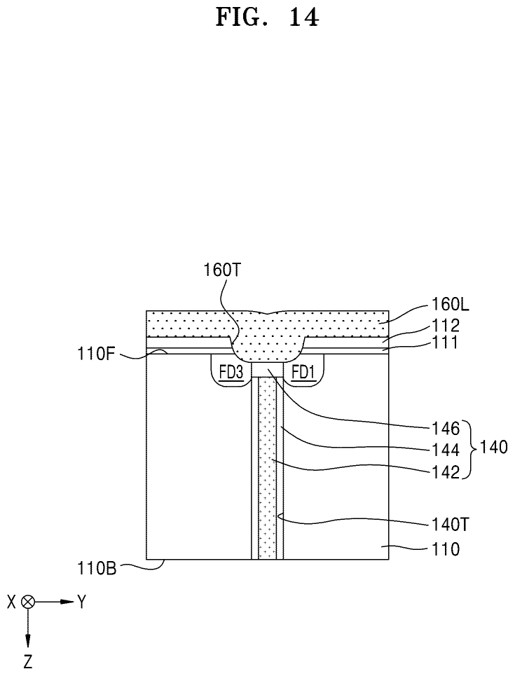

Referring to FIG. 14, a buried connect layer 160L may be formed in the buried connect trench 160T and on the first insulation layer 111 and the second insulation layer 112. In some embodiments, a portion overlapping the buried connect trench 160T in the vertical direction (the Z direction) may have a shape which is recessed toward the front-side surface 110F of the first semiconductor substrate 110.

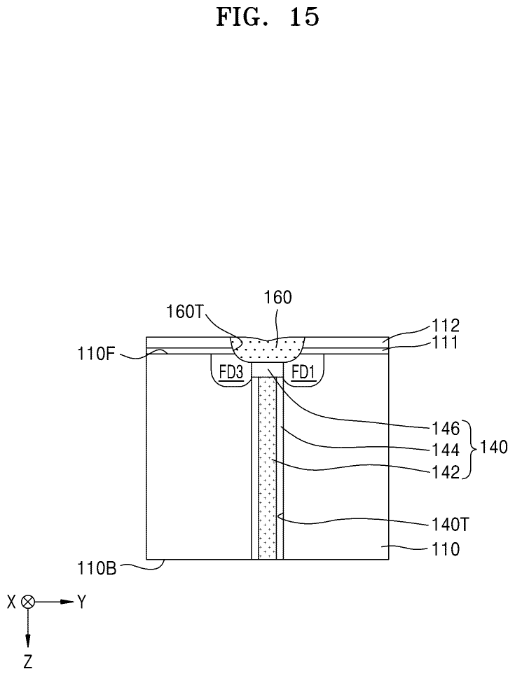

Referring to FIG. 15, a buried connect 160 may be formed by removing a portion of the buried connect layer 160L formed on the first insulation layer 111 and the second insulation layer 112. In detail, a process of removing a portion of the buried connect layer 160L may be performed by using a chemical mechanical polishing (CMP) process. A process of performing the CMP process may include a process of stopping the CMP process when the first insulation layer 111 and the second insulation layer 112 are exposed in the middle of removing the buried connect layer 160L. Accordingly, a lower surface 160_2 of the buried connect 160 may be disposed at a vertical level (i.e., a vertical level which is higher in a +Z direction) which is higher than or equal to a lower surface 112_1 of the second insulation layer 112.

In some other embodiments, a process of removing a portion of the buried connect layer 160L may be performed by using an etch-back process.

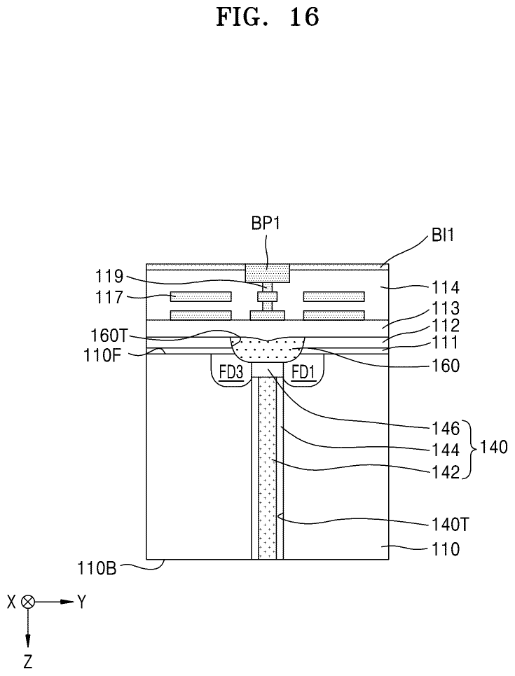

Referring to FIG. 16, a third insulation layer 113 may be formed on the buried connect 160 and the second insulation layer 112, and a wiring layer 117, a via 119, and a fourth insulation layer 114 surrounding the wiring layer 117 and the via 119 may be formed on the third insulation layer 113. Subsequently, a first bonding layer BI1 and a first bonding pad BP1 may be formed.

Subsequently, the image sensor 100 described above with reference to FIGS. 1 to 6 may be formed by performing a post process.

Based on the method of manufacturing the image sensor 100 described above with reference to FIGS. 12 to 16, the buried connect 160 according to an embodiment may be manufactured by using the hard mask layer HM which has been used in a previous process. Accordingly, the image sensor 100 where a manufacturing process is simplified may be provided.

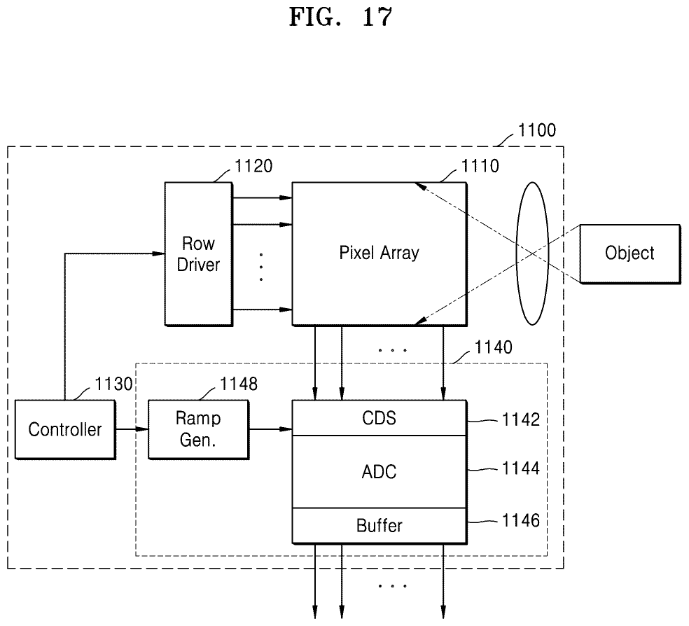

FIG. 17 is a block diagram illustrating a configuration of an image sensor 1100 according to an embodiment.

Referring to FIG. 17, the image sensor 1100 may include a pixel array 1110, a controller 1130, a row driver 1120, and a pixel signal processor 1140. The image sensor 1100 may include at least one of the image sensors 100, 101, 102, 103, and 200 described above with reference to FIGS. 1 to 11.

The pixel array 1110 may include a plurality of unit pixels which are two-dimensionally arranged, and each unit pixel may include a photoelectric conversion element. The photoelectric conversion element may absorb light to generate electric charge, and an electrical signal (an output voltage) based on the generated electric charge may be provided to the pixel signal processor 1140 through a vertical signal line. Unit pixels included in the pixel array 1110 may provide one output voltage at a time by row units, and thus, unit pixels of one row of the pixel array 1110 may be simultaneously activated by a selection signal output from the row driver 1120. Unit pixels of a selected row may output an output voltage based on absorbed light to an output line of a corresponding column.

The controller 1130 may allow the pixel array 1110 to absorb light and accumulate electric charge, or may control the row driver 1120 to temporarily store an accumulated electric charge and output an electrical signal based on a stored electric charge to the outside of the pixel array 1110. Also, the controller 1130 may control the pixel signal processor 1140 to measure an output voltage provided by the pixel array 1110.

The pixel signal processor 1140 may include a CDS 1142, an ADC 1144, and a buffer 1146. The CDS 1142 may sample and hold an output voltage provided by the pixel array 1110. The CDS 1142 may doubly sample a certain noise level and a level based on a generated output voltage to output a level corresponding to the difference therebetween. Also, the CDS 1142 may receive a ramp signal generated by a ramp signal generator 1148 and may compare ramp signals to output a comparison result.

The ADC 1144 may convert an analog signal, corresponding to a level received from the CDS 1142, into a digital signal. The buffer 1146 may latch the digital signal, and the latched digital signal may be sequentially output to the outside of the image sensor 1100 and may be transferred to an image processor (not shown).

Hereinabove, particular embodiments have been described in the drawings and the specification. The embodiments described herein have been used merely for describing the inventive concept and the description of any particular embodiment should not be used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While the inventive concept has been particularly shown and described with reference to embodiments thereof, it will be understood that various changes in form and details may be made therein without departing from the spirit and scope of the following claims.

What is claimed is:

1. An image sensor comprising:
a substrate including a front-side surface and a backside surface opposite thereto;
a first pixel disposed in the substrate, the first pixel including a first photoelectric conversion region;
a second pixel disposed adjacent to the first pixel in a first horizontal direction in the substrate, the second pixel including a second photoelectric conversion region, wherein the first horizontal direction is a direction parallel to the front-side surface of the substrate;
a pixel isolation structure disposed between the first pixel and the second pixel, the pixel isolation structure extending in a vertical direction and surrounding each of the first pixel and the second pixel, in the substrate, wherein the vertical direction is a direction normal to the front-side surface of the substrate;
a first floating diffusion region disposed adjacent to the front-side surface of the substrate in the first pixel;
a second floating diffusion region disposed adjacent to the front-side surface of the substrate in the second pixel;
an insulation layer disposed on the front-side surface of the substrate; and
a first buried connect passing through the insulation layer and connected to the first floating diffusion region and the second floating diffusion region,
wherein the first buried connect comprises an upper surface disposed in the substrate and a lower surface,
the upper surface of the first buried connect is disposed at a higher vertical level than an upper surface of the insulation layer, and
the lower surface of the first buried connect is disposed at a vertical level which is higher than or equal to a lower surface of the insulation layer.

2. The image sensor of claim 1, wherein the first floating diffusion region and the second floating diffusion region are spaced apart from each other in the first horizontal direction with the pixel isolation structure therebetween.

3. The image sensor of claim 2, wherein the first buried connect contacts the first floating diffusion region and the second floating diffusion region, and
the first floating diffusion region and the second floating diffusion region are electrically connected with each other by the first buried connect.

4. The image sensor of claim 1, wherein the lower surface of the first buried connect is disposed at a lower vertical level than the upper surface of the insulation layer.

5. The image sensor of claim 1, wherein the first buried connect comprises a material having an etch selectivity with the insulation layer.

6. The image sensor of claim 5, wherein the first buried connect comprises polysilicon.

7. The image sensor of claim 1, wherein the lower surface of the first buried connect comprises a portion recessed to an inner portion of the first buried connect.

8. The image sensor of claim 1, wherein the first buried connect comprises a portion overlapping the pixel isolation structure between the first pixel and the second pixel in the vertical direction.

9. The image sensor of claim 1, further comprising:
a third pixel disposed adjacent to the first pixel in the substrate in a second horizontal direction intersecting with the first horizontal direction, the third pixel including a third photoelectric conversion region;
a fourth pixel disposed adjacent to the second pixel in the substrate in the second horizontal direction, the fourth pixel including a fourth photoelectric conversion region;
a third floating diffusion region disposed adjacent to the front-side surface of the substrate, in the third pixel; and
a fourth floating diffusion region disposed adjacent to the front-side surface of the substrate, in the fourth pixel,
wherein the first buried connect is further connected to the third floating diffusion region and the fourth floating diffusion region.

10. The image sensor of claim 1, further comprising:
a third pixel disposed adjacent to the first pixel in the substrate in a second horizontal direction intersecting with the first horizontal direction, the third pixel including a third photoelectric conversion region;
a fourth pixel disposed adjacent to the second pixel in the substrate in the second horizontal direction, the fourth pixel including a fourth photoelectric conversion region;
a third floating diffusion region disposed adjacent to the front-side surface of the substrate, in the third pixel;
a fourth floating diffusion region disposed adjacent to the front-side surface of the substrate, in the fourth pixel; and
a second buried connect passing through the insulation layer and contacting the third floating diffusion region and the fourth floating diffusion region.

11. An image sensor comprising:
a substrate including a front-side surface and a backside surface opposite thereto;
a first pixel disposed in the substrate, the first pixel including a first photoelectric conversion region;
a second pixel disposed adjacent to the first pixel in a first horizontal direction in the substrate, the second pixel including a second photoelectric conversion region, wherein the first horizontal direction is a direction parallel to the front-side surface of the substrate;
a pixel isolation structure disposed between the first pixel and the second pixel, the pixel isolation structure extending in a vertical direction and surrounding each of the first pixel and the second pixel, in the substrate, wherein the vertical direction is a direction normal to the front-side surface of the substrate;
a first floating diffusion region disposed adjacent to the front-side surface of the substrate, in the first pixel;
a second floating diffusion region disposed adjacent to the front-side surface of the substrate, in the second pixel;
an insulation layer disposed on the front-side surface of the substrate; and
a buried connect passing through the insulation layer and connected to the first floating diffusion region and the second floating diffusion region,
wherein an uppermost portion of a lower surface of the buried connect is disposed at a vertical level which is higher than or equal to a lower surface of the insulation layer, and
an upper surface of the buried connect is disposed at a higher vertical level than the front-side surface of the substrate.

12. The image sensor of claim 11, wherein the buried connect contacts each of the first floating diffusion region and the second floating diffusion region, between the first floating diffusion region and the second floating diffusion region.

13. The image sensor of claim 11, wherein the buried connect comprises portions each overlapping the first floating diffusion region and the second floating diffusion region in the vertical direction.

14. The image sensor of claim 11, wherein the lower surface of the buried connect is disposed at a lower vertical level than an upper surface of the insulation layer.

15. The image sensor of claim 11, wherein the buried connect comprises a material having an etch selectivity with the insulation layer.

16. The image sensor of claim 15, wherein the buried connect comprises polysilicon.

17. The image sensor of claim 15, wherein the insulation layer comprises silicon nitride.

18. The image sensor of claim 11, wherein the buried connect comprises a portion buried in the substrate.

19. An image sensor comprising:
a substrate including a front-side surface and a backside surface opposite thereto;
a first pixel disposed in the substrate, the first pixel including a plurality of first photoelectric conversion regions;
a second pixel disposed adjacent to the first pixel in a first horizontal direction in the substrate, the second pixel including a plurality of second photoelectric conversion regions, wherein the first horizontal direction is a direction parallel to the front-side surface of the substrate;
a third pixel disposed adjacent to the first pixel in the substrate in a second horizontal direction intersecting with the first horizontal direction, the third pixel including a plurality of third photoelectric conversion regions;
a fourth pixel disposed adjacent to the second pixel in the substrate in the second horizontal direction, the fourth pixel including a plurality of fourth photoelectric conversion regions;
a pixel isolation structure extending in a vertical direction in the substrate, surrounding each of the first pixel, the second pixel, the third pixel, and the fourth pixel, and extending in the first horizontal direction and the second horizontal direction, wherein the vertical direction is a direction normal to the front-side surface of the substrate;
a first floating diffusion region disposed adjacent to the front-side surface of the substrate and shared by the plurality of first photoelectric conversion regions, in the first pixel;
a second floating diffusion region disposed adjacent to the front-side surface of the substrate and shared by the plurality of second photoelectric conversion regions, in the second pixel;
a third floating diffusion region disposed adjacent to the front-side surface of the substrate and shared by the plurality of third photoelectric conversion regions, in the third pixel;
a fourth floating diffusion region disposed adjacent to the front-side surface of the substrate and shared by the plurality of fourth photoelectric conversion regions, in the fourth pixel;
an insulation layer disposed on the front-side surface of the substrate;
a buried connect contacting the first floating diffusion region to the fourth floating diffusion region and including a portion passing through the insulation layer and buried in the substrate; and
a color filter and a lens, each disposed on the backside surface of the substrate,
wherein the buried connect comprises a material having an etch selectivity with the insulation layer,
an uppermost portion of a lower surface of the buried connect is disposed at a vertical level which is higher than or equal to a lower surface of the insulation layer, and
an upper surface of the buried connect is disposed at a higher vertical level than the front-side surface of the substrate.

20. The image sensor of claim 19, wherein the insulation layer comprises silicon nitride, and
the buried connect comprises polysilicon.
